(19) United States
(12) Patent Application Publication
(10) Pub. No.: US 2025/0056729 A1
(43) Pub. Date: Feb. 13, 2025

(54) SUBSTRATE

(71) Applicant: Murata Manufacturing Co., Ltd., Kyoto (JP)

(72) Inventor: Ryuichi KUBO, Kyoto (JP)

(21) Appl. No.: 18/930,079

(22) Filed: Oct. 29, 2024

Related U.S. Application Data
(63) Continuation of application No. PCT/JP2023/005690, filed on Feb. 17, 2023.

(30) Foreign Application Priority Data
Jun. 27, 2022 (JP) 2022-102606

(51) Int. Cl. H05K 1/18; H05K 3/30

(52) U.S. Cl. CPC H05K 1/185; H05K 3/305; H05K 2201/0266; H05K 2203/1305

(57) ABSTRACT

A substrate includes a core substrate that has a first surface, a second surface facing away from the first surface, and a cavity portion therein; at least two electronic components provided in the cavity portion; and an encapsulating material that is provided between the cavity portion and the at least two electronic components and between the at least two electronic components and includes a resin and fillers, in which an average of distances between the at least two electronic components is less than a shortest distance between a wall surface of the cavity portion and some of the electronic components that are adjacent to the wall surface.

### CROSS REFERENCE TO RELATED APPLICATION

This is a continuation of International Application No. PCT/JP2023/005690 filed on Feb. 17, 2023 which claims priority from Japanese Patent Application No. 2022-102606 filed on Jun. 27, 2022. The contents of these applications are incorporated herein by reference in their entireties.

### BACKGROUND OF THE DISCLOSURE

### Field of the Disclosure

The present disclosure relates to a substrate.

### Description of the Related Art

Patent Document 1 describes a semiconductor package including a core member, a through-hole that passes through the core member, one or more passive components disposed in the through-hole, and an encapsulating material that covers at least some portions of the passive components and fills at least a portion of the through-hole (see, for example, FIG. 9).

Patent Document 2 describes a printed wiring board including a core substrate that has a cavity passing through a core material, a plurality of types of electronic components that are housed in the cavity, and a resin that is formed in the cavity and fixes the plurality of types of electronic components to the core substrate (see, for example, FIG. 1).
Patent Document 1: Japanese Patent No. 6694931
Patent Document 2: Japanese Unexamined Patent Application Publication No. 2019-207978

### BRIEF SUMMARY OF THE DISCLOSURE

Conventionally, since lands for solder connection are to be formed on the substrate to surface-mount electronic components on a substrate, the distances between electronic components must be several hundred micrometers or more, and reducing the distances is difficult.

On the other hand, according to the technologies described in Patent Documents 1 and 2, wiring can be electrically connected, through vias, to electronic components embedded in the cavity portion of the core substrate. Accordingly, the distances between electronic components can be further reduced.

However, when the distances between electronic components are reduced, the gaps between electronic components may be insufficiently filled with the encapsulating material for encapsulating the electronic components in the substrate.

The present disclosure addresses the problem described above with a possible benefit of providing a substrate having good filling properties of the encapsulating material between electronic components.

A substrate according to the present disclosure includes: a core substrate that has a first surface, a second surface facing away from the first surface, and a cavity portion therein; at least two electronic components provided in the cavity portion; and an encapsulating material that is provided between the cavity portion and the at least two electronic components and between the at least two electronic components, the encapsulating material including a resin and fillers, in which an average of distances between the at least two electronic components is less than a shortest distance between a wall surface of the cavity portion and some of the electronic components that are adjacent to the wall surface.

According to the present disclosure, it is possible to provide a substrate having good filling properties of the encapsulating material between electronic components.

### BRIEF DESCRIPTION OF THE SEVERAL VIEWS OF THE DRAWINGS

FIG. 1 is a sectional view schematically illustrating an example of a substrate according to an embodiment of the present disclosure.

FIG. 2 is a plan view schematically illustrating an example of a core substrate and electronic components included in the substrate illustrated in FIG. 1.

FIG. 3 is an enlarged schematic sectional view of a cavity portion of the substrate illustrated in FIG. 1.

FIG. 4 is a plan view schematically illustrating encapsulation of the electronic components with an encapsulating material.

FIG. 5 is a sectional view schematically illustrating encapsulation of the electronic components with the encapsulating material.

FIG. 6 is a plan view schematically illustrating a state in which the core substrate of the substrate illustrated in FIG. 1 has been deformed.

FIG. 7 is a sectional view schematically illustrating a modification of the substrate illustrated in FIG. 1.

FIG. 8 is a diagram schematically illustrating an example of a process of attaching an adhesive film for fixing electronic components to the core substrate.

FIG. 9 is a sectional view schematically illustrating an example of a process of disposing the electronic components (passive components) on the adhesive film.

FIG. 10 is a sectional view schematically illustrating an example of a process of disposing the electronic components (passive components and a semiconductor chip) on the adhesive film.

FIG. 11 is a sectional view schematically illustrating an example of a process of filling the cavity portion of the core substrate with the encapsulating material.

FIG. 12 is a sectional view schematically illustrating an example of a process of forming vias.

FIG. 13 is a sectional view schematically illustrating an example of a process of forming a wiring layer.

FIG. 14 is a sectional view schematically illustrating an example of a process of forming buildup layers.

### DETAILED DESCRIPTION OF THE DISCLOSURE

A substrate according to the present disclosure will be described.

However, the present disclosure is not limited to the following structure and can be applied while being modified as appropriate without departing from the concept of the present disclosure. It should be noted that a combination of two or more desirable configurations described below also constitutes the present disclosure.

### Substrate

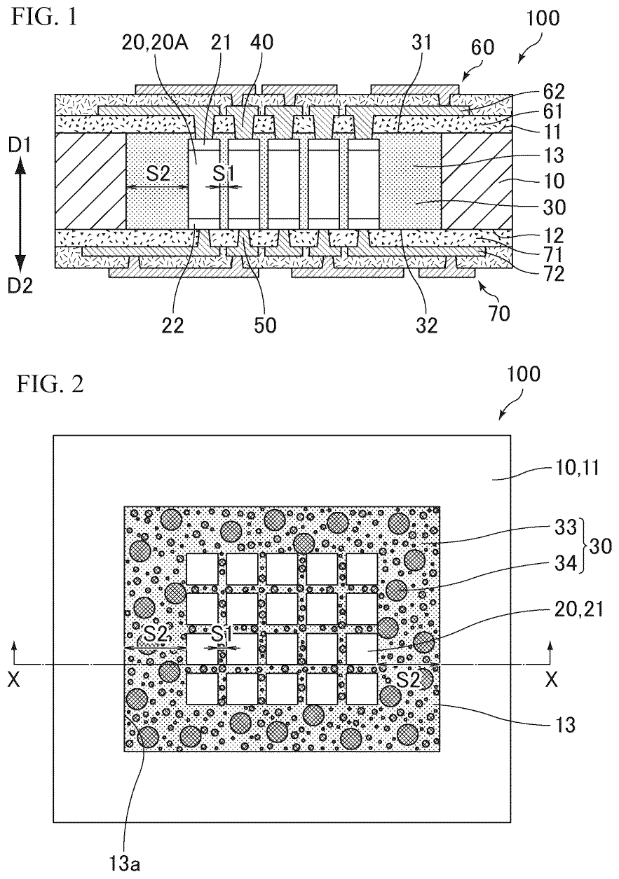

FIG. 1 is a sectional view schematically illustrating an example of a substrate according to an embodiment of the present disclosure. FIG. 2 is a plan view schematically illustrating an example of a core substrate and an electronic component included in the substrate illustrated in FIG. 1. It should be noted that FIG. 1 is a sectional view taken along line X-X in FIG. 2.

A substrate 100 illustrated in FIGS. 1 and 2 includes a core substrate 10 that has a first surface 11, a second surface 12 facing away from the first surface 11, and a cavity portion 13 therein; at least two electronic components 20 provided in the cavity portion 13; and an encapsulating material 30 that is provided between the cavity portion 13 and the at least two electronic components 20 and between the at least two electronic components 20 and includes a third surface 31 close to the first surface 11 and a fourth surface 32 close to the second surface 12; a plurality of first via conductors 40 that pass through the third surface 31 of the encapsulating material 30 and are electrically connected to first electrodes 21 of the at least two electronic components 20; a plurality of second via conductors 50 that are electrically connected to second electrodes 22 of the at least two electronic components 20; a first buildup layer (rewiring layer) 60 provided on the first surface 11 of the core substrate 10 and the third surface 31 of the encapsulating material 30; and a second buildup layer (rewiring layer) 70 provided on the second surface 12 of the core substrate 10 and the fourth surface 32 of the encapsulating material 30.

The core substrate 10 may be a resin substrate, a glass substrate, a ceramic substrate, or the like. The core substrate 10 may also be a printed wiring board having conductor wiring thereon or therein. The core substrate 10 may be an insulating support substrate (core material) formed of a resin, such as an epoxy resin, and a reinforcing material, such as a glass cloth. The support substrate may contain inorganic particles, such as silica particles and alumina particles.

The first surface 11 and the second surface 12 of the core substrate 10 are parallel to each other and constitute a pair of main surfaces of the core substrate 10 that face away from each other.

The cavity portion 13 of the core substrate 10 passes through the core substrate 10. The shape of the cavity portion 13 in plan view of the core substrate 10 is not particularly limited and may be a circle, an ellipse, an oval, a n-gon (n is an integer of 5 or more), or the like in addition to a rectangle illustrated in FIG. 2.

The substrate 100 is a component-embedded substrate in which the plurality of electronic components 20 are embedded, and the electronic components 20 are not disposed on the first surface 11 and the second surface 12 of the core substrate 10 but in the cavity portion 13 of the core substrate 10.

The electronic components 20 may be disposed two-dimensionally in the cavity portion 13 as illustrated in FIG. 2 or may be placed one-dimensionally in the cavity portion 13. In the former case, the electronic components 20 may be arranged, for example, in a matrix (FIG. 2) or in a staggered manner.

The distances S1 between the plurality of electronic components 20 (that is, the distances between adjacent electronic components 20) are not particularly limited, but the average of the distances S1 may be 10 μm or more and 100 μm or less, may also be 10 μm or more and 50 μm or less.

Here, the average of the distances S1 is obtained by image analysis of a photograph of the substrate 100. More specifically, an enlarged photograph of a cross section parallel to the second surface 12 of the core substrate 10 is taken by a scanning electron microscope (SEM) or a transmission electron microscope (TEM), line segments are drawn on opposing outlines for each set of adjacent electronic components 20 by using image analysis software, and the average distance between the line segments is obtained. Then, the average value of the average distances obtained from all combinations of the electronic components 20 is obtained, and the average value is determined as the average of the distances S1. A radiograph may be used instead of a photograph taken by a scanning electron microscope (SEM) or a transmission electron microscope (TEM).

It should be noted that the distances S1 between the electronic components 20 may be substantially constant (identical between all sets) as illustrated in FIGS. 1 and 2 or may vary depending on the measurement position or the target electronic components 20.

In addition, the average of the distances S1 need only be measured in one cross section parallel to the second surface 12 and need not necessarily be measured in two or more cross sections parallel to the second surface 12.

In addition, FIG. 1 illustrates a cross section orthogonal to the second surface 12 of the core substrate 10. Here, “cross section orthogonal to the second surface 12” may also be referred to below simply as “vertical cross section”.

The type of the electronic components 20 is not particularly limited, but a passive component 20A, such as a capacitor (for example, a multilayer ceramic capacitor (MLCC)) or an inductor, is disposed in this example. The electronic components 20 (passive component 20A) are chip components having an elongated shape, such as a rectangular parallelepiped shape or a columnar shape.

It should be noted that, in a single cavity portion 13, a single type of the electronic components 20 may be disposed or two or more types of the electronic components 20 may be disposed in a mixed manner. In addition, in the latter case, the electronic components 20 of a single type have a single size standardized according to the size notation of the chip components. The size notation is defined by JIS (Japanese Industrial Standards) and EIA (Electronic Industries Alliance), and an example of notation in JIS is 0603. In addition, the electronic components 20 of a single type may be the same basic components of electrical circuits, such as capacitors or inductors. In addition, the electronic components 20 of a single type may be capacitors or inductors of a single model.

The electronic components 20 have a longitudinal direction parallel to a direction (first direction D1 or second direction D2 described later) orthogonal to the second surface 12 of the core substrate 10. In this case, it is particularly difficult to fill the gaps between the electronic components 20 with the encapsulating material 30, but in the embodiment, the filling properties of the encapsulating material 30 between the electronic components 20 can be improved as described later.

In a vertical cross section, the dimensions of each of the electronic components 20 in the direction (first direction D1 or second direction D2 described later) orthogonal to the second surface 12 of the core substrate 10 are greater than the dimensions in the direction parallel to the second surface 12. Accordingly, the electronic components 20 can be disposed with higher density.

In addition, each of the electronic components 20 has a first electrode 21 in a first direction D1 that is orthogonal to the second surface 12 of the core substrate 10 and faces the first surface 11 and has a second electrodes 22 in a second direction D2 that is opposite to the first direction D1. The electronic components 20 having an elongated shape can be disposed with higher density by being mounted in the vertical direction as described above.

The first electrode 21 and the second electrode 22 of each of the electronic components 20 are located in one end portion and the other end portion, respectively, in the longitudinal direction of the electronic component 20 having an elongated shape.

It should be noted that, in a vertical cross section, at least one dimension of the electronic component 20 in a direction (first direction D1 or second direction D2) orthogonal to the second surface 12 of the core substrate 10 may be smaller than that in a direction parallel to the second surface 12. In addition, in at least one of the electronic components 20, the first electrode 21 and the second electrode 22 may be disposed in a direction parallel to the core substrate 10.

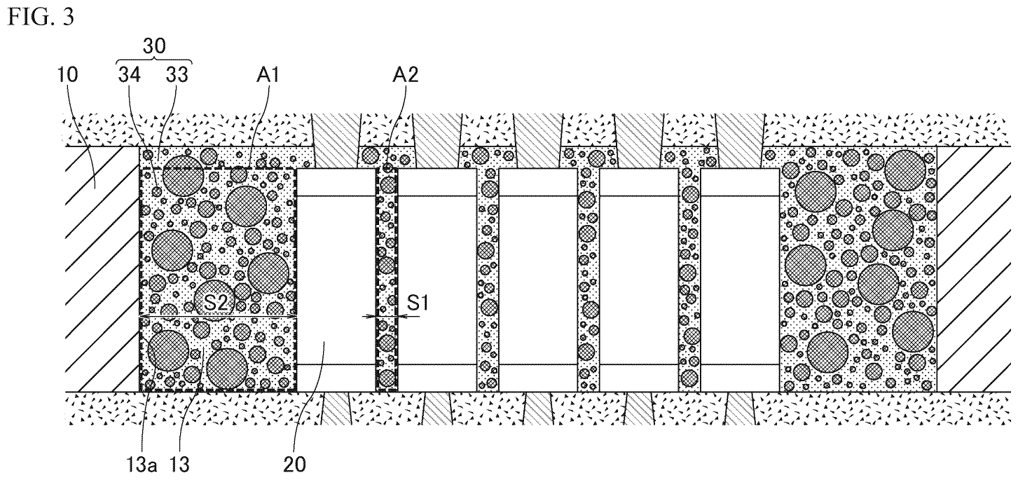

FIG. 3 is an enlarged schematic sectional view of a cavity portion of the substrate illustrated in FIG. 1. It should be noted that FIG. 3 is a portion of a sectional view taken along line X-X in FIG. 2 and illustrates a vertical cross section.

The encapsulating material 30 is a member for encapsulating the electronic components 20 in the cavity portion 13 and fills the space around the electronic components 20 in the cavity portion 13. As illustrated in FIGS. 2 and 3, the encapsulating material 30 includes a resin 33 and the fillers 34.

The resin 33 may be, for example, an epoxy resin, a polyimide, or the like, and may also be an epoxy resin.

The fillers 34 include particles as illustrated in FIGS. 2 and 3. For example, the fillers 34 may be inorganic particles, such as silica particles or alumina particles.

As described above, the filler 34 may include SiO₂ or Al₂O₃, and the filler 34 may include at least one of SiO₂ and Al₂O₃.

The shape of the filler 34 is not particularly limited and may be, for example, spherical as illustrated in FIGS. 2 and 3, oval-spherical, planar, needle-like, amorphous, or the like.

At least one first via conductor 40 is provided for each of the electronic components 20, and the electronic component 20 is electrically connected to the first buildup layer 60 via each of the first via conductors 40. Each of the first via conductors 40 passes through at least the insulating layer 61 of the first buildup layer 60 closest to the core substrate 10 and the third surface 31 of the encapsulating material 30 and reaches the first electrode 21 of the corresponding electronic component 20.

At least one second via conductor 50 is provided for each of the electronic components 20, and the electronic component 20 is electrically connected to the second buildup layer 70 via the at least one second via conductor 50. The second via conductor 50 passes through at least an insulating layer 71 of the second buildup layer 70 that is closest to the core substrate 10 and reaches the second electrode 22 of the corresponding electronic component 20.

The first buildup layer 60 electrically connects the electronic components 20 to each other or the electronic components 20 to other components, through-holes, terminals, or the like. In the first buildup layer 60, at least one insulating layer 61 and at least one wiring layer 62 are alternately laminated with each other.

Similarly, the second buildup layer 70 electrically connects the electronic components 20 to each other or the electronic components 20 to other components, through-holes, terminals, or the like. In the second buildup layer 70, at least one insulating layer 71 and at least one wiring layer 72 are alternately laminated with each other.

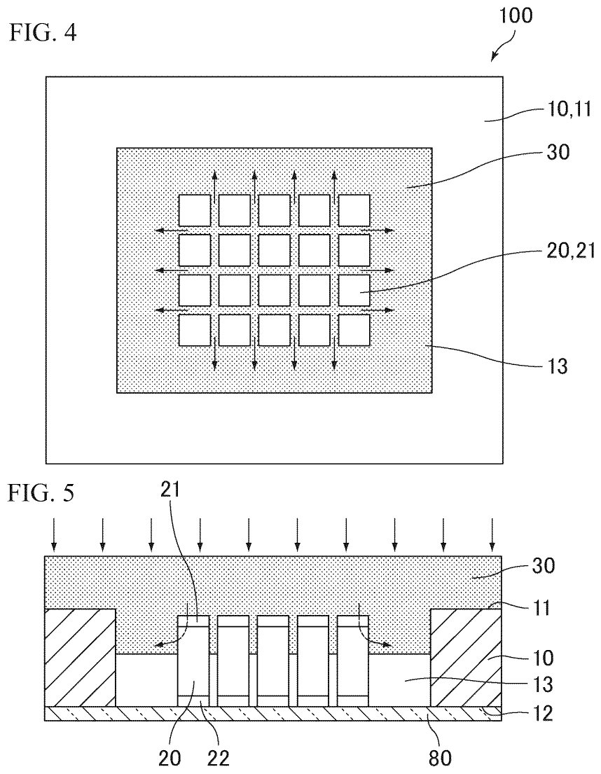

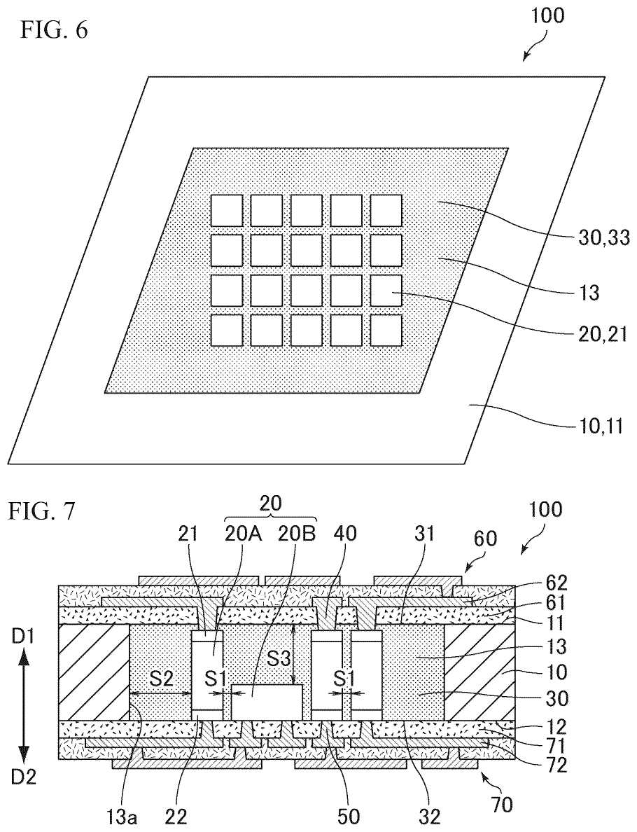

FIG. 4 is a plan view schematically illustrating encapsulation of the electronic components with an encapsulating material. FIG. 5 is a sectional view schematically illustrating encapsulation of the electronic components with the encapsulating material. FIG. 6 is a plan view schematically illustrating a state in which the core substrate included in the substrate illustrated in FIG. 1 has been deformed.

In the embodiment, as illustrated in FIGS. 2 and 3, the average of the distances S1 of the plurality of electronic components 20 is less than a shortest distance S2 between a wall surface 13a of the cavity portion 13 and the electronic components 20 adjacent to the wall surface 13a. Since there is space around a region in which the electronic components 20 are mounted, when the electronic components 20 are encapsulated with the encapsulating material 30, as illustrated in FIGS. 4 and 5, space around a region in which the electronic components 20 are mounted enables the encapsulating material 30 to flow toward the surrounding portions, thereby improving the flowability of the encapsulating material 30. Since this suppresses bubbles from being mixed and the fillers 34 from being held, the filling properties of the encapsulating material 30 between the electronic components 20 can be improved.

In addition, in the embodiment, the electrodes (first electrode 21 and second electrode 22) of the electronic component 20 are located in one end portion and the other end portion in the longitudinal direction of the electronic component 20 having an elongated shape. When the electrodes are disposed at such positions, the positions of the electrodes coincide with the positions at which the fillers 34 come into contact with the electrodes during filling with the encapsulating material 30. Since the material of the electrodes is typically a metal, which is stronger than portions (typically ceramic) other than the electrodes, the electrodes are not easily damaged even when the fillers 34 come into contact with the electrodes.

On the other hand, since the distances between the plurality of electronic components 20 are small and the large fillers 34 do not easily enter the gaps between the electronic components 20, the large fillers 34 are prevented from coming into contact with ceramic portions other than the end portions of the electronic components 20 in the longitudinal direction of the electronic components 20 between the electronic components 20. Accordingly, the ceramic portions of the electronic components 20 between the plurality of electronic components 20 are prevented from being damaged.

For the reasons described above, providing the electrodes at such positions prevents the electronic components 20 from being damaged by being contact with the fillers 34 during filling with the encapsulating material 30.

In addition, since it is possible to sufficiently ensure that the frame of the resin 33 of the encapsulating material 30 has a lower elastic modulus than the core substrate 10, the stress from the core substrate 10 that occurs when the core substrate 10 is deformed as illustrated in FIG. 6 can be relaxed by the frame portion, and stress applied to the electronic components 20 can be reduced. That is, even when the core substrate 10 is deformed, the wide outer periphery of the encapsulating material 30 serves as a buffer, and the effect on the electronic components 20 can be reduced.

The ratio of the average of the distances S1 to the shortest distance S2 is not particularly limited, but the shortest distance S2 may be five times or more the average of the distances S1, may also be eight times or more, and may further be virtually 10 times or more.

In addition, the shortest distance S2 is not particularly limited but may be 50 μm or more, and may also be 100 μm or more.

Here, the shortest distance S2 is obtained by image analysis of a photograph of the substrate 100. More specifically, an enlarged photograph of a cross section parallel to the second surface 12 of the core substrate 10 is taken by a scanning electron microscope (SEM) or a transmission electron microscope (TEM), for the wall surface 13a of the cavity portion 13 and each of the electronic components 20 adjacent to the wall surface 13a, line segments are drawn on opposing outlines by using image analysis software, and the minimum distance between the line segments is obtained. Then, the shortest distance of the obtained minimum distances is determined as the shortest distance S2. A radiograph may be used instead of a photograph taken by a scanning electron microscope (SEM) or a transmission electron microscope (TEM).

As illustrated in FIGS. 2 and 3, all the distances S1 between the plurality of electronic components 20, that is, all the distances S1 between the adjacent electronic components 20 may be shorter than the shortest distance S2.

As illustrated in FIG. 3, in a vertical cross section, the average particle diameter of the fillers 34 that fill a region A1 between the wall surface 13a of the cavity portion 13 and the plurality of electronic components 20 adjacent to the wall surface 13a may be greater than the average particle diameter of the fillers 34 that fill a region A2 between the plurality of electronic components 20.

When there are many fillers 34 having a large particle diameter in the region A1, the filling ratio of the fillers 34 is likely to decrease. When the filling ratio of the fillers 34 is small, the ratio of the resin 33 is large. Since a resin having a low elastic modulus can be disposed around the electronic components 20, the stress from the core substrate 10 can be further relaxed.

That is, in a vertical cross section, the ratio of the occupied area of the fillers 34 that fill the region A1 between the wall surface 13a of the cavity portion 13 and the plurality of electronic components 20 adjacent to the wall surface 13a may be smaller than the ratio of the occupied area of the fillers 34 that fill the region A2 between the plurality of electronic components 20. It should be noted that the filling ratio of the fillers 34 can be determined as the ratio of the occupied area of the fillers 34 per unit region in an image in a vertical cross section.

By adjusting the filling ratio of the fillers 34 in the region A1, it is possible to adjust the linear expansion coefficient of the encapsulating material 30 and the heat shrinkage of the encapsulating material 30 during the solidification, and suppress the occurrence of cracks and the stress on the electronic components 20.

It is difficult for the region A2 between the plurality of electronic components 20 to be filled with the fillers 34 having a large particle diameter but it is easy for the region A1 between the wall surface of the cavity portion 13 and the plurality of electronic components 20 adjacent to the wall surface 13a of the cavity portion 13 to be filled with the fillers 34 having a large particle diameter. That is, the fillers 34 having a large particle diameter are unevenly distributed in the region A1. It is possible to artificially make the properties of the encapsulating material 30 in the implementation area of the electronic components 20 differ from the properties of the encapsulating material 30 in a region around the implementation area by using the feature described above to make the material of the fillers 34 having a large particle diameter differ from the material of the fillers 34 having a small particle diameter.

Characteristics of the encapsulating material 30 that depend on the material of the fillers 34 are, for example, the linear expansion coefficient, the dielectric constant, Young's modulus, thermal conductivity, electromagnetic wave absorption, moisture absorption, and the like.

In one example, the thermal conductivity of the fillers 34 having a small particle diameter is increased, and the thermal conductivity of the fillers 34 having a large particle diameter is decreased. In this case, the thermal conductivity of the encapsulating material 30 in the region A2 increases, and the thermal conductivity of the encapsulating material 30 in the region A1 decreases. As a result, the heat generated by the electronic components 20 in the cavity portion 13 can be efficiently released to the upper and lower surfaces of the substrate 100 without being released in a direction (lateral direction) parallel to the second surface 12.

In an example of the combination of the fillers 34 as described above, silica is used as the fillers 34 having a large particle diameter, and boron nitride or aluminum nitride is used as the fillers 34 having a small particle diameter.

In another example, electromagnetic wave absorption functionality is added to the fillers 34 having a large particle diameter. In this case, the electromagnetic shielding performance of the encapsulating material 30 in the region A1 increases. As a result, the effect of the noise from the outside of the cavity portion 13 can be blocked while the electrical characteristics of the encapsulating material 30 of the region (region A2) around the electronic components 20 are maintained.

In an example of the combination of the fillers 34 as described above, iron oxide is used as the fillers 34 having a large particle diameter.

In another example, a material having a small dielectric constant and low dielectric loss is used as the fillers 34 having a small particle diameter, and a material having a small linear expansion coefficient is used as the fillers 34 having a large particle diameter. This can reduce the physical effect of heat because the linear expansion coefficient of the encapsulating material 30 decreases in the region A1 while improving the electrical characteristics (reducing loss) of the electronic components 20 in the encapsulating material 30 in the region (region A2) around the electronic components 20.

In an example of the combination of the fillers 34, a zirconium phosphate compound (such as ULTEA manufactured by Toagosei Co., Ltd.) is used as the fillers 34 having a large particle diameter, and silica is used as the fillers 34 having a small particle diameter.

In another example, a material having a small dielectric constant and low dielectric loss is used as the fillers 34 having a small particle diameter, and a material having high thermal conductivity is used as the fillers 34 having a large particle diameter. As a result, heat can be efficiently released from the cavity portion 13 through the encapsulating material 30 of the region A while the electrical characteristics of the electronic components 20 in the encapsulating material 30 in the region (region A2) around the electronic components 20 are improved (loss is reduced).

In an example of the combination of the fillers 34 as described above, boron nitride or aluminum nitride is used as the fillers 34 having a large particle diameter and silica is used as the fillers 34 having a small particle diameter.

In addition, when many fillers 34 having a large particle diameter are included in the encapsulating material 30 in the region A1, the continuity of a fracture surface is inhibited. That is, the encapsulating material 30 is more unlikely to be broken.

It should be noted that the average particle diameter of the fillers 34 is obtained by image analysis of a photograph of a vertical cross section. More specifically, in an enlarged photograph of a vertical cross section obtained by a scanning electron microscope (SEM) or a transmission electron microscope (TEM), for at least 50 fillers 34 contained in the region A1 or A2, the diameters (that is, the equivalent circle diameters) of circles having the same areas as the area inside the closed curve formed by individual outlines are obtained, and the average value of the diameters is determined as the average particle diameter of the fillers 34.

It should be noted that it is difficult to determine whether the cross section of the filler 34 in the photograph is a cross section cut near the center at which the particle diameter of the filler 34 is large or a cross section cut near an end portion at which the particle diameter of the filler 34 is small, but the particle diameter, the shape, the area, and the like of the filler 34 are obtained in accordance with an image of the cross section of the filler 34.

As illustrated in FIG. 3, the region A1 may be the entire region sandwiched between the wall surface 13a of the cavity portion 13 and the electronic components 20 adjacent to the wall surface 13a in a vertical cross section. In addition, the region A2 may be the entire region sandwiched between at least one pair (or individual pairs) of adjacent electronic components 20 in a vertical cross section.

In addition, two wall surfaces 13a of the cavity portion 13 are generally present in a vertical cross section, but, in this case, the region A2 may be a region between one of the wall surfaces 13a and the electronic component 20 adjacent to this wall surface 13a.

In addition, the position in a vertical cross section for the comparison of the average particle diameter is not particularly limited and the position may be located in a cross section in which the plurality of electronic components 20 and the gaps between adjacent electronic components 20 are located, as illustrated in FIG. 3. In addition, a vertical cross section for the comparison of the average particle diameter may be or need not be a cross section in which the shortest distance S2 is located.

It should be noted that the average particle diameter of the fillers 34 that fill the region A1 and the average particle diameter of the fillers 34 that fill the region A2 need only satisfy the relationship described above in only one vertical cross section, and the relationship need not necessarily satisfy the relationship described above in two or more vertical cross sections.

Although the ratio of these average particle diameters is not particularly limited, the average particle diameter of the fillers 34 that fill the region A1 may be equal to or more than five times the average particle diameter of the fillers 34 that fill the region A2, and may also be equal to or more than 10 times.

The average particle diameter of the fillers 34 that fill the region A1 may be 10 μm or more and 100 μm or less, and may also be 50 μm or more and 100 μm or less.

The average particle diameter of the fillers 34 that fill the region A2 may be 10 nm or more and 100 μm or less, and may also be 10 nm or more and 50 μm or less.

In addition, in a cross section (vertical cross section) orthogonal to the second surface 12, the maximum particle diameter of the fillers 34 that fill the region between the wall surface 13a and the plurality of electronic components 20 adjacent to the wall surface 13a may be greater than the maximum particle diameter of the fillers 34 that fill the region between the plurality of electronic components 20.

That is, the maximum particle diameter of the fillers 34 that fill the region A1 may be greater than the maximum particle diameter of the fillers 34 that fill the region A2.

The maximum particle diameter of the fillers 34 that fill the region A1 may be 10 μm or more and 100 μm or less, and may also be 50 μm or more and 100 μm or less.

The maximum particle diameter of the fillers 34 that fill the region A2 may be 10 nm or more and 100 μm or less, and may also be 10 nm or more and 50 μm or less.

In addition, in a cross section (vertical cross section) orthogonal to the second surface 12, the maximum particle diameter of the fillers 34 that fill the region A1 between the wall surface 13a and the plurality of electronic components 20 adjacent to the wall surface 13a may be greater than the average of the distances S1 between the plurality of electronic components 20. This indicates that the region A1 includes the filler 34 that cannot fill the gaps between the electronic components 20.

It should be noted that the maximum particle diameter of the fillers 34 is obtained by image analysis of a photograph of a vertical cross section. More specifically, in an enlarged photograph of a vertical cross section obtained by a scanning electron microscope (SEM) or a transmission electron microscope (TEM), for the fillers 34 contained in the region A1 or A2, the diameters (that is, the equivalent circle diameters) of circles having the same areas as closed curves formed by individual outlines are obtained, and the maximum value of the diameters is determined as the maximum particle diameter of the fillers 34.

FIG. 7 is a sectional view schematically illustrating a modification of the substrate illustrated in FIG. 1.

As illustrated in FIG. 7, a semiconductor chip 20B, such as an integrated circuit (IC), may be mounted together with the passive components 20A as the electronic components 20 in a mixed manner in the cavity portion 13 of the core substrate 10. In this case, as illustrated in FIG. 7, the average of the distances S1 is calculated using not only the distance S1 (average distance) between the passive components 20A but also the distance S1 (average distance) between the passive component 20A and the semiconductor chip 20B.

It should be noted that, in this modification, the semiconductor chip 20B may be disposed adjacent to the wall surface 13a of the cavity portion 13, and in this case, the shortest distance S2 may be the distance between the wall surface 13a and the semiconductor chip 20B adjacent to the wall surface 13a. In addition, in this case, the region A1 may be the region between the wall surface 13a and the semiconductor chip 20B adjacent to the wall surface 13a in a vertical cross section.

Furthermore, in the modification, the region A2 may include a region sandwiched between at least one pair (or individual pairs) consisting of a passive component 20A and a semiconductor chip 20B adjacent to each other in a vertical cross section.

In addition, for at least some of the plurality of electronic components 20, the thickness of the encapsulating material 30 in a direction orthogonal to the second surface 12 from the surface of the electronic component 20 may be greater than the average of the distances S1 between the plurality of electronic components 20.

In addition, for at least some of the plurality of electronic components 20, the average particle diameter of the fillers 34 that fill a region in which the thickness of the encapsulating material 30 in a direction orthogonal to the second surface 12 from the surface of the electronic component 20 is greater than the average of the distances S1 between the plurality of electronic components 20 may be greater than the average particle diameter of the fillers 34 that fill the region between the plurality of electronic components 20.

This condition is met for the semiconductor chip 20B in FIG. 7, and a thickness S3 of the encapsulating material 30 present on the upper surface of the semiconductor chip 20B is greater than the average of the distances S1. Under the conditions, the fillers 34 having a large particle diameter can be present in the encapsulating material 30 located on the semiconductor chip 20B. In addition, the average particle diameter of the fillers 34 present in the region is greater than the average particle diameter of the fillers 34 that fill the region between the plurality of electronic components 20.

When the fillers 34 having a larger particle diameter are formed of a material having high thermal conductivity, the heat dissipation from the semiconductor chip 20B to the third surface 31 of the encapsulating material 30 can be improved.

In addition, when the fillers 34 having a large particle diameter are formed of a material having high electromagnetic wave absorption performance, the effect of external noise on the semiconductor chip 20B can be blocked.

When the fillers 34 having a larger particle diameter are formed of a material having a smaller linear expansion coefficient, the linear expansion coefficient of the encapsulating material 30 decreases to reduce the physical effect of heat on the semiconductor chip 20B.

### Method of Manufacturing Substrate

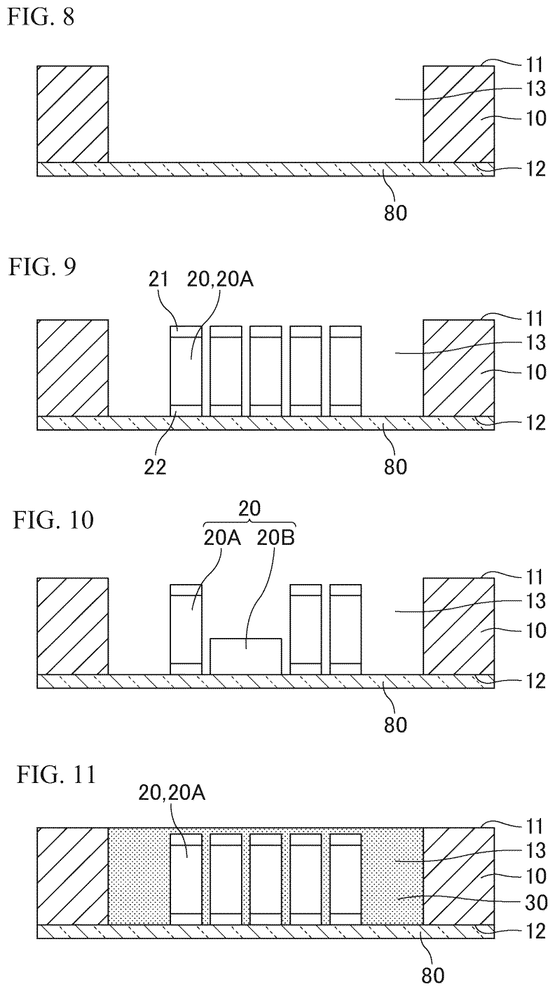

The substrate 100 can be manufactured by the following method. FIG. 8 is a diagram schematically illustrating an example of a process of attaching an adhesive film for fixing electronic components to the core substrate.

First, as illustrated in FIG. 8, the cavity portion 13 is formed in the core substrate 10, and the adhesive film 80 for fixing the electronic components is attached to the second surface 12 of the core substrate 10.

FIG. 9 is a sectional view schematically illustrating an example of a process of disposing electronic components (passive components) on the adhesive film. FIG. 10 is a sectional view schematically illustrating an example of a process of disposing electronic components (passive components and a semiconductor chip) on the adhesive film.

Next, as illustrated in FIG. 9, the plurality of electronic components 20 (passive components 20A) are disposed on the adhesive film 80. The passive components 20A are disposed on the adhesive film 80 such that, for example, the first electrodes 21 face upward and the second electrodes 22 face downward. As a result, the second electrodes 22 are attached to the adhesive film 80. At this time, as illustrated in FIG. 10, the passive components 20A and the semiconductor chip 20B may be mounted in a mixed manner.

FIG. 11 is a sectional view schematically illustrating an example of a process of filling a cavity portion of the core substrate with the encapsulating material.

Next, as illustrated in FIG. 11, the electronic components 20 are encapsulated with the encapsulating material 30. Specifically, under vacuum, an unsolidified film including a thermo-setting resin and the fillers is laminated on the first surface 11 of the core substrate 10. Then, this film is heat-pressed to be softened, and the space around the electronic components 20 in the cavity portion 13 is filled with the thermo-setting resin and the fillers. At this time, since the average of the distances S1 between the electronic components 20 is less than the shortest distance S2 between the wall surface 13a and the electronic components 20 as described above, the softened material flows from the mount area of the electronic components 20 toward the surroundings, and accordingly, the gaps between the electronic components 20 can be effectively filled with the material. Then, the thermo-setting resin hardens to form the encapsulating material 30 that sufficiently fills the region between the electronic components 20.

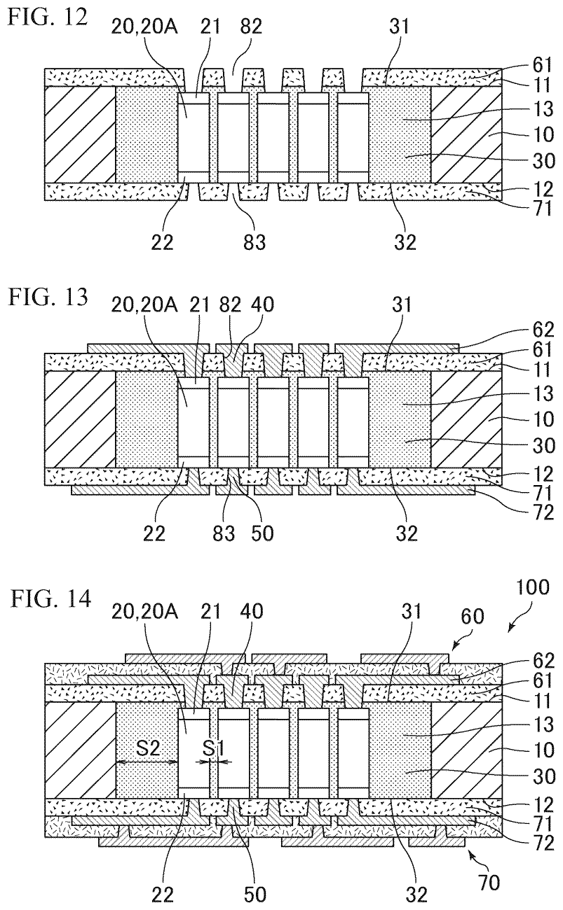

FIG. 12 is a sectional view schematically illustrating an example of a process of forming vias.

Next, as illustrated in FIG. 12, after the adhesive film 80 is removed, the insulating layer 61 is formed on the first surface 11 of the core substrate 10 and the third surface 31 of the encapsulating material 30, and the insulating layer 71 is formed on the second surface 12 of the core substrate 10 and the fourth surface 32 of the encapsulating material 30. It should be noted that the adhesive film 80 can be used continuously without being removed. Then, a via 82 is formed in the insulating layer 61 by a CO₂ laser to expose the first electrode 21, and a via 83 is formed in the insulating layer 71 to expose the second electrode 22.

FIG. 13 is a sectional view schematically illustrating an example of a process of forming a wiring layer.

Next, as illustrated in FIG. 13, the vias 82 and 83 are filled by using plating (for example, a semi-additive method) to form the first and second via conductors 40 and 50 and the wiring layers 62 and 72.

FIG. 14 is a sectional view schematically illustrating an example of a process of forming buildup layers.

Next, as illustrated in FIG. 14, a layer is added as necessary, and the first buildup layer 60 and the second buildup layer 70 are formed.

As described above, the substrate 100 can be manufactured.

The disclosure of this specification will be described below.
<1> A substrate comprising: a core substrate that has a first surface, a second surface facing away from the first surface, and a cavity portion therein; at least two electronic components provided in the cavity portion; and an encapsulating material that is provided between the cavity portion and the at least two electronic components and between the at least two electronic components, the encapsulating material including a resin and fillers, wherein an average of distances between the at least two electronic components is less than a shortest distance between a wall surface of the cavity portion and some of the at least two electronic components that are adjacent to the wall surface.
<2> The substrate according to <1>, wherein, in a cross section orthogonal to the second surface, an average particle diameter of the fillers that fill a region between the wall surface and the some of the at least two electronic components that are adjacent to the wall surface is greater than an average particle diameter of the fillers that fill a region between the at least two electronic components.
<3> The substrate according to <2>, wherein, in a cross section orthogonal to the second surface, a ratio of an occupied area of the fillers that fill the region between the wall surface and the some of the at least two electronic components that are adjacent to the wall surface is smaller than a ratio of an occupied area of the fillers that fill the region between the at least two electronic components.
<4> The substrate according to any one of <1> to <3>, wherein, in a cross section orthogonal to the second surface, a maximum particle diameter of the fillers that fill the region between the wall surface and the some of the at least two electronic components that are adjacent to the wall surface is greater than a maximum particle diameter of the fillers that fill the region between the at least two electronic components.
<5> The substrate according to any one of <1> to <4>, wherein, in a cross section orthogonal to the second surface, the maximum particle diameter of the fillers that fill the region between the wall surface and the some of the at least two electronic components that are adjacent to the wall surface is greater than an average of distances between the at least two electronic components.
<6> The substrate according to any one of <1> to <5>, wherein each of the at least two electronic components is shaped to have a longitudinal direction that extends in a direction orthogonal to the second surface.
<7> The substrate according to <6>, wherein electrodes of each of the at least two electronic components are located at one end and another end in the longitudinal direction.
<8> The substrate according to any one of <1> to <7>, wherein, for at least some of the at least two electronic components, a thickness of the encapsulating material in a direction orthogonal to the second surface from surfaces of the at least two electronic components is greater than the average of the distances between the at least two electronic components.
<9> The substrate according to <8>, wherein an average particle diameter of the fillers that fill a region in which, for at least some of the at least two electronic components, the thickness of the encapsulating material in the direction orthogonal to the second surface from the surfaces of the at least two electronic components is greater than the average of the distances between the at least two electronic components is greater than the average particle diameter of the fillers that fill the region between the at least two electronic components.
10 core substrate
11 first surface
12 second surface
13 cavity portion
13a wall surface
20 electronic component
20A passive component
20B semiconductor chip
21 first electrode
22 second electrode
30 encapsulating material
31 third surface
32 fourth surface
33 resin
34 filler
40 first via conductor
50 second via conductor
60 first buildup layer
61 insulating layer
62 wiring layer
70 second buildup layer
71 insulating layer
72 wiring layer
80 adhesive film
82, 83 via
100 substrate
D1 first direction
D2 second direction
S1 distance between adjacent electronic components
S2 shortest distance between wall surface of cavity portion and electronic component adjacent to wall surface
S3 thickness of encapsulating material on upper surface of semiconductor chip
A1 region between wall surface of cavity portion and electronic components adjacent to wall surface
A2 region between electronic components

1. A substrate comprising:
a core substrate having a first surface, a second surface facing away from the first surface, and a cavity portion therein;
at least two electronic components provided in the cavity portion; and
an encapsulating material provided between the cavity portion and the at least two electronic components and between the at least two electronic components, the encapsulating material including a resin and fillers,
wherein an average of distances between the at least two electronic components is less than a shortest distance between a wall surface of the cavity portion and some of the at least two electronic components being adjacent to the wall surface.

2. The substrate according to claim 1,
wherein, in a cross section orthogonal to the second surface, an average particle diameter of the fillers filling a region between the wall surface and the some of the at least two electronic components being adjacent to the wall surface is greater than an average particle diameter of the fillers filling a region between the at least two electronic components.

3. The substrate according to claim 2,
wherein, in a cross section orthogonal to the second surface, a ratio of an occupied area of the fillers filling the region between the wall surface and the some of the at least two electronic components being adjacent to the wall surface is smaller than a ratio of an occupied area of the fillers filling the region between the at least two electronic components.

4. The substrate according to claim 1,
wherein, in a cross section orthogonal to the second surface, a maximum particle diameter of the fillers filling the region between the wall surface and the some of the at least two electronic components being adjacent to the wall surface is greater than a maximum particle diameter of the fillers filling the region between the at least two electronic components.

5. The substrate according to claim 1,
wherein, in a cross section orthogonal to the second surface, the maximum particle diameter of the fillers filling the region between the wall surface and the some of the at least two electronic components being adjacent to the wall surface is greater than an average of distances between the at least two electronic components.

6. The substrate according to claim 1,
wherein each of the at least two electronic components is shaped to have a longitudinal direction extending in a direction orthogonal to the second surface.

7. The substrate according to claim 6,
wherein electrodes of each of the at least two electronic components are located at one end and another end in the longitudinal direction.

8. The substrate according to claim 1,
wherein, for at least some of the at least two electronic components, a thickness of the encapsulating material in a direction orthogonal to the second surface from surfaces of the at least two electronic components is greater than the average of the distances between the at least two electronic components.

9. The substrate according to claim 8,
wherein an average particle diameter of the fillers filling a region in which, for at least some of the at least two electronic components, the thickness of the encapsulating material in the direction orthogonal to the second surface from the surfaces of the at least two electronic components is greater than the average of the distances between the at least two electronic components is greater than the average particle diameter of the fillers filling the region between the at least two electronic components.

10. The substrate according to claim 2,
wherein, in a cross section orthogonal to the second surface, a maximum particle diameter of the fillers filling the region between the wall surface and the some of the at least two electronic components being adjacent to the wall surface is greater than a maximum particle diameter of the fillers filling the region between the at least two electronic components.

11. The substrate according to claim 3,
wherein, in a cross section orthogonal to the second surface, a maximum particle diameter of the fillers filling the region between the wall surface and the some of the at least two electronic components being adjacent to the wall surface is greater than a maximum particle diameter of the fillers filling the region between the at least two electronic components.

12. The substrate according to claim 2,
wherein, in a cross section orthogonal to the second surface, the maximum particle diameter of the fillers filling the region between the wall surface and the some of the at least two electronic components being adjacent to the wall surface is greater than an average of distances between the at least two electronic components.

13. The substrate according to claim 3,
wherein, in a cross section orthogonal to the second surface, the maximum particle diameter of the fillers filling the region between the wall surface and the some of the at least two electronic components being adjacent to the wall surface is greater than an average of distances between the at least two electronic components.

14. The substrate according to claim 4,
wherein, in a cross section orthogonal to the second surface, the maximum particle diameter of the fillers filling the region between the wall surface and the some of the at least two electronic components being adjacent to the wall surface is greater than an average of distances between the at least two electronic components.

15. The substrate according to claim 2,
wherein each of the at least two electronic components is shaped to have a longitudinal direction extending in a direction orthogonal to the second surface.

16. The substrate according to claim 3,
wherein each of the at least two electronic components is shaped to have a longitudinal direction extending in a direction orthogonal to the second surface.

17. The substrate according to claim 4,
wherein each of the at least two electronic components is shaped to have a longitudinal direction extending in a direction orthogonal to the second surface.

18. The substrate according to claim 5,
wherein each of the at least two electronic components is shaped to have a longitudinal direction extending in a direction orthogonal to the second surface.

19. The substrate according to claim 2,
wherein, for at least some of the at least two electronic components, a thickness of the encapsulating material in a direction orthogonal to the second surface from surfaces of the at least two electronic components is greater than the average of the distances between the at least two electronic components.

20. The substrate according to claim 3,
wherein, for at least some of the at least two electronic components, a thickness of the encapsulating material in a direction orthogonal to the second surface from surfaces of the at least two electronic components is greater than the average of the distances between the at least two electronic components.
